(19) United States
(12) Patent Application Publication
(10) Pub. No.: US 2016/0245856 A1
(43) Pub. Date: Aug. 25, 2016

(54) PARTIAL DISCHARGE SENSOR

(71) Applicant: MITSUBISHI ELECTRIC CORPORATION, Tokyo (JP)

(72) Inventors: Takashi YANAGI, Tokyo (JP); Toru FUKASAWA, Tokyo (JP); Satoru YOSHIDA, Tokyo (JP); Takashi ITO, Tokyo (JP)

(73) Assignee: MITSUBISHI ELECTRIC CORPORATION, Tokyo (JP)

(21) Appl. No.: 15/026,013

(22) PCT Filed: Oct. 1, 2013
(86) PCT No.: PCT/JP2013/076717

§ 371 Date: Mar. 30, 2016

(51) Int. Cl. G01R 31/12

(52) U.S. Cl. CPC G01R 31/1254

(57) ABSTRACT

With regard to a top loaded monopole antenna consisting of a disk 5 and a metal post 6, a partial discharge sensor includes a short-circuit conductor 10 joining the metal post 6 to a covering 7 and a coaxial line composed of a hole 8 and a metal terminal 9. This makes it possible to implement a partial discharge sensor that can suppress the induction of high voltage in the disk 5 and can achieve high sensitivity in a frequency band of a partial discharge to be detected.

### TECHNICAL FIELD

The present invention relates to a partial discharge sensor for detecting a partial discharge phenomenon that occurs in a metallic casing of an electric power device such as a gas insulated switching device and a vacuum breaker.

### BACKGROUND ART

For example, a gas insulated switching device is an electric power device that supports a high voltage conductor (electric wire) in an insulated state in the metallic casing that hermetically seals an insulating gas.

Although the electric field distribution in the metallic casing is designed so as to form a uniform electric field, if a defect (such as a foreign substance and a needle-like projection) forming a nonuniform electric field is mixed, a partial discharge may occur from a part of the defect as its origin.

If the partial discharge is left as it is, it may bring about dielectric breakdown that can lead to an accident. Accordingly, it is important to detect an early state of the partial discharge to prevent the dielectric breakdown.

In addition, as for a vacuum breaker utilizing the high insulation in a vacuum state, if the degree of vacuum lowers, a partial discharge may occur because of the degradation of the insulation performance. In this case also, if the partial discharge is left as it is, since the dielectric breakdown may occur, it is important to detect the partial discharge early.

Thus, a partial discharge sensor is required which detects the partial discharge to ensure the safety of an electric power device.

As a partial discharge sensor, there is one that detects the partial discharge by receiving high-frequency waves generated by the partial discharge with the antenna provided in its metallic casing.

For example, the following Patent Document 1 discloses a partial discharge sensor that can adjust the spacing between the disk of a top loaded monopole antenna installed in a cylindrical branch pipe and the inside diameter of the branch pipe, thereby being able to be set up even when the inside diameter of the branch pipe is small.

Incidentally, since a high voltage conductor is disposed in the metallic casing, stray capacitance is formed across the high voltage conductor and the disk of the top loaded antenna. Accordingly, if the disk of the top loaded antenna is insulated from the metallic casing, a high voltage is induced in the disk of the top loaded antenna.

Since the induced high voltage can have an adverse effect on a measuring instrument of the partial discharge sensor, it is desirable for the partial discharge sensor installed in the metallic casing that the disk and the metallic casing are conductive at the low frequency used for the high voltage conductor.

In the foregoing Patent Document 1, the round column of the top loaded antenna and the covering of the branch pipe are joined through a short stub with an electrical length of one quarter of the wavelength corresponding to the specific frequency of the frequency band of the partial discharge to be detected.

### PRIOR ART DOCUMENT

### Patent Document

Patent Document 1: WO2012/137254

### DISCLOSURE OF THE INVENTION

### Problems to be Solved by the Invention

Since the conventional partial discharge sensor is arranged as described above, the frequency of the high-frequency wave signal emitted from the partial discharge because of the reduction in the degree of vacuum in a vacuum breaker, for example, is 200-300 MHz, and the short stub with the electrical length of one quarter of the wavelength corresponding to the frequency has a length of 375 mm at most. Accordingly, when the inside diameter of the branch pipe is small, it cannot contain the short stub, which offers a problem of making it difficult to eliminate the adverse effect of the high voltage induced in the disk of the top loaded antenna.

The present invention is implemented to solve the foregoing problems. Therefore it is an object of the present invention to provide a partial discharge sensor capable of eliminating the adverse effect of the high voltage induced in the disk of the top loaded antenna even if the frequency band of the partial discharge to be detected is low.

### Means for Solving the Problem

A partial discharge sensor in accordance with the present invention comprises: a cylindrical metallic casing; a cylindrical branch pipe having its first end joined to an opening of the metallic casing; a covering metallic conductor covering a second end of the branch pipe; a flat metallic conductor disposed in the opening of the metallic casing in a manner that the flat metallic conductor is on the same level with an internal surface of the metallic casing without making contact with the metallic casing; a metal post disposed inside the branch pipe in a manner that the metal post has its first end joined to the flat metallic conductor; a metal terminal having its first end joined to a second end of the metal post, and having its second end exposed to the outside through a hole provided at the center of the covering metallic conductor; and a short-circuit conductor having its first end joined to the metal post, and its second end joined to the covering metallic conductor, wherein the length of the short-circuit conductor is less than one quarter of the wavelength corresponding to the frequency of a partial discharge to be detected.

### Advantages of the Invention

According to the present invention, even if the frequency band of the partial discharge to be detected is low, it offers an advantage of being able to eliminate the adverse effect of the high voltage induced in the disk of the top loaded antenna.

### BRIEF DESCRIPTION OF THE DRAWINGS

FIG. 1 is a cross-sectional view showing a partial discharge sensor of an embodiment 1 in accordance with the present invention;

FIG. 2 is a top view seen from the arrow A of FIG. 1;

FIG. 3 is a cross-sectional view showing an enlargement of a hole 8 and its surroundings of a covering 7;

FIG. 4 is an equivalent circuit showing the impedance seen looking into a top loaded monopole antenna from the position indicated by a symbol B of FIG. 3;

FIG. 5 is a diagram showing a result of a simulation which calculates received voltage characteristics of the top loaded monopole antenna consisting of a disk 5 and a metal post 6;

FIG. 6 is a cross-sectional view showing a partial discharge sensor of an embodiment 2 in accordance with the present invention;

FIG. 7 is a cross-sectional view showing another partial discharge sensor of the embodiment 2 in accordance with the present invention;

FIG. 8 is a cross-sectional view showing a partial discharge sensor of an embodiment 3 in accordance with the present invention; and

FIG. 9 is a cross-sectional view showing a partial discharge sensor of an embodiment 4 in accordance with the present invention.

### BEST MODE FOR CARRYING OUT THE INVENTION

The best mode for carrying out the invention will now be described with reference to the accompanying drawings.

### Embodiment 1

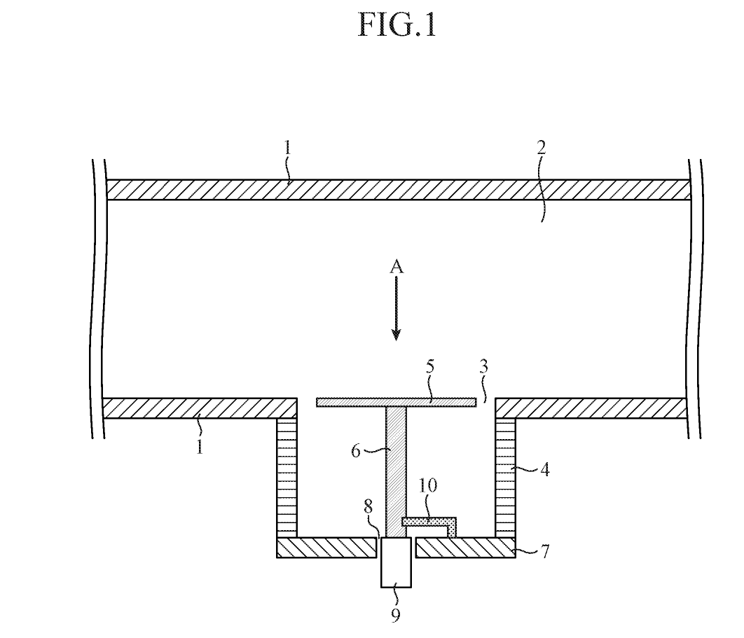

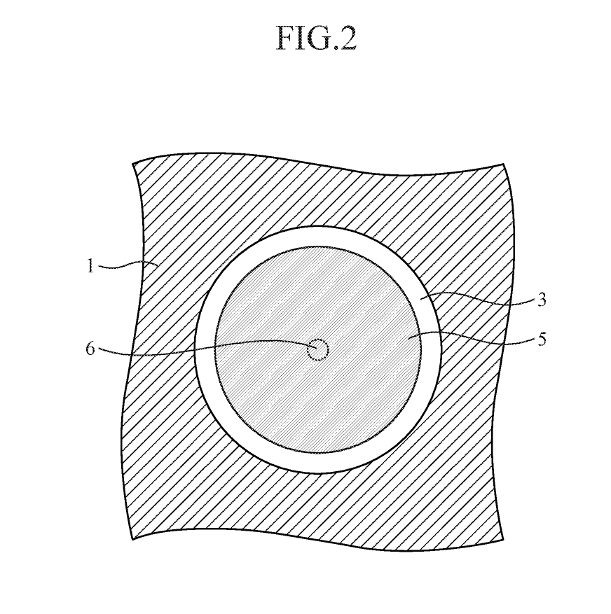

FIG. 1 is a cross-sectional view showing a partial discharge sensor of an embodiment 1 in accordance with the present invention; and FIG. 2 is a top view seen from the arrow A of FIG. 1.

In FIG. 1 and FIG. 2, a metallic casing 1 is a metallic structure constructed in such a manner as to form a cylindrical closed space 2 in its inside, which corresponds to a main tank of a gas insulated switching device.

The closed space 2 is filled with an insulating gas, and a high voltage electric wire (not shown) is disposed. In addition, the surface of the metallic casing 1 is placed at the ground potential.

An opening 3 is a hole formed in the metallic casing 1. Although FIG. 2 shows an example in which the hole is circular, the shape of the opening 3 is not limited to a circle, but can be selected freely such as a rectangle. However, to prevent the sensitivity of the partial discharge sensor from having angular characteristics, it is desirable to select an axially symmetric shape.

A branch pipe 4 is made of a metallic cylinder, and its inner wall section has the same shape as the opening 3 of the metallic casing 1. The branch pipe 4 has its first end joined to the opening 3 of the metallic casing 1.

A disk 5 is a flat metallic conductor disposed in the opening 3 of the metallic casing 1 without making contact with the metallic casing 1. A surface of the disk 5 (the upper surface in FIG. 1) is approximately aligned with the plane of the opening 3.

A metal post 6 is a conductor which is disposed inside the branch pipe 4 and is joined to a second surface of the disk 5. It supports the disk 5 in such a manner that the disk 5 does not make direct contact with the metallic casing 1 or a covering 7. Although FIG. 2 shows an example in which the metal post 6 is a round column, it is not limited to the round column, but can be a square column.

Incidentally, the disk 5 and the metal post 6 constitute the top loaded monopole antenna.

The covering 7, which is a covering metallic conductor that covers the second end of the branch pipe 4, is electrically connected to the metallic casing 1 via the branch pipe 4. Accordingly, the surface of the branch pipe 4 and covering 7 are also placed at the ground potential.

A hole 8 is provided approximately at the center of the covering 7.

The shape of a section perpendicular to the axis of the hole 8 is a circle, for example. However, as will be described later, as for the coaxial line comprised of the hole 8 and a metal terminal 9, it is enough that the coaxial line is built so as to become a prescribed low impedance line (constructed so that the characteristic impedance of the coaxial line is lower than the characteristic impedance of a transmission line to be connected to a second end of the metal terminal 9), and any shape can be selected as its form.

The metal terminal 9, which is a rod-like conductor, is disposed in such a manner that the central axis of the metal terminal 9 is approximately aligned with the central axis of the hole 8, and is passed through the hole 8 of the covering 7.

The metal terminal 9 has its first end joined to the metal post 6, and has its second end exposed to the outside.

A short-circuit conductor 10 is a conductor that has its first end joined to the metal post 6, and its second end joined to the covering 7.

Next, the operation will be described.

The gas insulated switching device is a switchgear that switches on or off a high-voltage power line (not shown) mounted in the metallic casing 1. At this time, a partial discharge can sometimes occur in the metallic casing 1 owing to some reasons.

As the reasons, the following cases are conceived.

(1) A partial discharge occurs owing to a local high electric field because of an alien substances mixed into the metallic casing 1.

(2) In the case of a vacuum breaker, although the switchgear is mounted in the vacuum container to insulate between the terminals of the switchgear, when the degree of vacuum in the vacuum container lowers, the insulation performance reduces, thereby bringing about a partial discharge.

If a partial discharge occurs, a discharge source of the partial discharge emits high-frequency waves.

In the present embodiment 1, the top loaded monopole antenna comprised of the disk 5 and the metal post 6 receives the high-frequency waves emitted from the discharge source, and transmits the signal of the high-frequency waves (referred to as a “high-frequency wave signal” from now on) to the outside through the metal terminal 9.

Detecting the high-frequency wave signal with an external measuring instrument makes it possible to detect that a partial discharge occurs inside the metallic casing 1 from the intensity and/or frequency of the high-frequency wave signal.

Although the frequency of the high-frequency waves emitted from the partial discharge varies depending on a location where the discharge occurs or the like, the high-frequency waves from a VHF band to a UHF band are mainly observed.

To obtain a high-frequency wave signal with a high signal level at the external measuring instrument, it is necessary to improve the sensitivity of the partial discharge sensor at a prescribed frequency.

The top loaded monopole antenna comprised of the disk 5 and the metal post 6 has high performance when the impedance makes series resonance at the prescribed frequency. Accordingly, the diameter of the disk 5 and the length of the metal post 6 should be designed in accordance with the inside diameter of the branch pipe 4 so that the impedance forms the series resonance at the prescribed frequency.

Here, to transmit the high-frequency wave signal to the external measuring instrument, the disk 5, metal post 6 and metal terminal 9 must be insulated from the metallic casing 1, branch pipe 4 and covering 7 which are placed at the ground potential.

On the other hand, since the high-voltage power line is disposed inside the metallic casing 1, a high voltage is induced in the high-voltage power line and the disk 5.

When the high voltage induced in the high-voltage power line and disk 5 is supplied to the external measuring instrument via the metal terminal 9, there is a risk of causing damage of the measuring instrument.

Thus, in the present embodiment 1, the short-circuit conductor 10 connects the metal post 6 to the covering 7 so as to discharge the high voltage induced in the high-voltage power line and the disk 5 to the ground potential.

In addition, in the present embodiment 1, since the length of the short-circuit conductor 10 is set at a length shorter than one quarter of the wavelength corresponding to the specific frequency in the frequency band of the partial discharge to be detected, it operates as a parallel inductance for the high-frequency wave signal.

On the other hand, as for the current flowing through the high-voltage power line, since it has the commercial frequency of 50 Hz or 60 Hz, which is much lower than the frequency of the high-frequency waves emitted from the discharge source, the short-circuit conductor 10 can prevent the high voltage from occurring without short-circuiting the high-frequency wave signal.

The impedance characteristic of the top loaded monopole antenna comprised of the disk 5 and the metal post 6 will now be described in more detail.

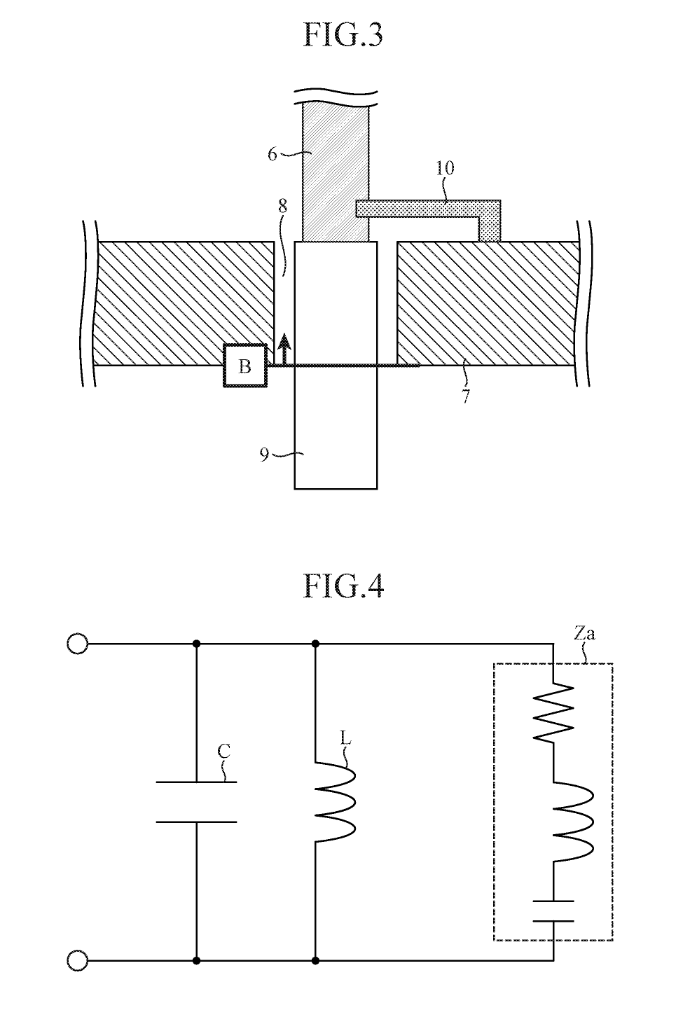

FIG. 3 is a cross-sectional view showing an enlargement of the hole 8 and its surroundings of the covering 7.

Since the central axis of the metal terminal 9 is approximately aligned with the central axis of the hole 8 provided in the covering 7, a coaxial line is formed which is comprised of the metal terminal 9 functioning as its internal conductor and of the hole 8 of the covering 7 functioning as its external conductor.

At this time, the characteristic impedance of the coaxial line is determined by a cross-sectional shape of the hole 8 and that of the metal terminal 9 of the covering 7.

When the cross-sectional shape of the hole 8 and that of the metal terminal 9 of the covering 7 are circular, the characteristic impedance Z0 of the coaxial line is proportional to log(D/d), where D is the diameter of the hole 8 and d is the diameter of the metal terminal 9 (where, D/d>1).

Here, when designing D/d at approximately one, the characteristic impedance Z0 of the coaxial line has a low value. At this time, the coaxial line formed by the hole 8 and metal terminal 9 operates as a parallel capacitance.

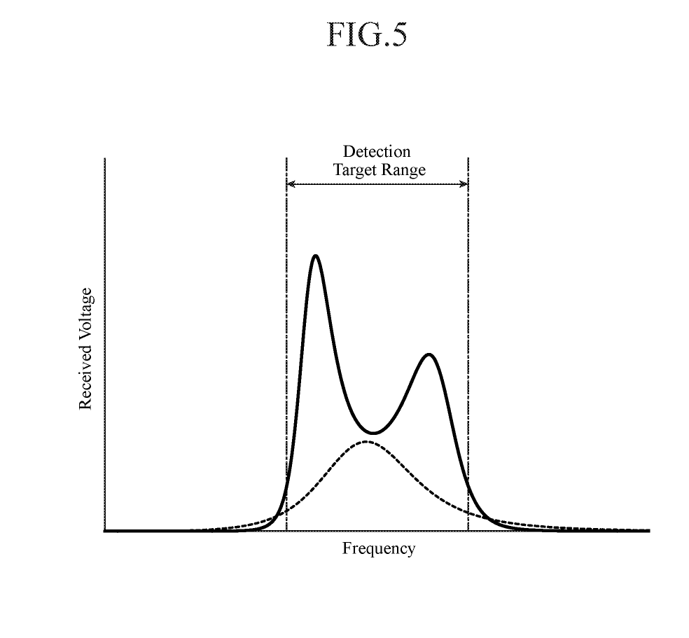

Thus, in FIG. 3, the impedance seen looking into the top loaded monopole antenna comprised of the disk 5 and the metal post 6 from the position designated by the symbol B is equivalent to a circuit shown in FIG. 4.

In FIG. 4, Za is a series resonant circuit denoting the impedance characteristic of the top loaded monopole antenna itself comprised of the disk 5 and the metal post 6, L is the inductance formed by the short-circuit conductor 10, C is the capacitance of the coaxial line comprised of the hole 8 and the metal terminal 9.

As shown in FIG. 4, connecting the parallel resonant circuit to the series resonant circuit makes it possible to broaden the band of the impedance. Utilizing the effect enables the partial discharge sensor of the present embodiment 1 to reduce a mismatch loss in the frequency band of the partial discharge to be detected, thereby being able to improve the sensitivity in average.

FIG. 5 is a diagram showing a result of a simulation that calculates the received voltage characteristics of the top loaded monopole antenna comprised of the disk 5 and the metal post 6.

In FIG. 5, a solid line shows the received voltage characteristics of the top loaded monopole antenna in the present embodiment 1. In addition, a broken line shows the received voltage characteristics of the top loaded monopole antenna without the short-circuit conductor 10 and the metal terminal 9 to make the effect of the present invention clearer.

It is found from FIG. 5 that the received voltage increases in the frequency band of the partial discharge to be detected in the present embodiment 1, thereby being able to implement a partial discharge sensor with a higher sensitivity.

As is clear from the above, according to the present embodiment 1, it is configured in such a manner that as for the top loaded monopole antenna comprised of the disk 5 and the metal post 6, it comprises the short-circuit conductor 10 joining the metal post 6 and the covering 7, and the coaxial line comprised of the hole 8 and the metal terminal 9. Accordingly, it offers an advantage of being able to suppress the induction of the high voltage in the disk 5, and thus to prevent an adverse effect on the measuring instrument, and to implement a partial discharge sensor with a higher sensitivity in the frequency band of the partial discharge to be detected.

In addition, according to the present embodiment 1, since the length of the short-circuit conductor 10 is made shorter than one quarter of the wavelength corresponding to the specific frequency in the frequency band of the partial discharge to be detected, even if the inside diameter of the branch pipe 4 is small compared with the wavelength, the short-circuit conductor 10 can be disposed, which enables constructing a small-sized partial discharge sensor.

### Embodiment 2

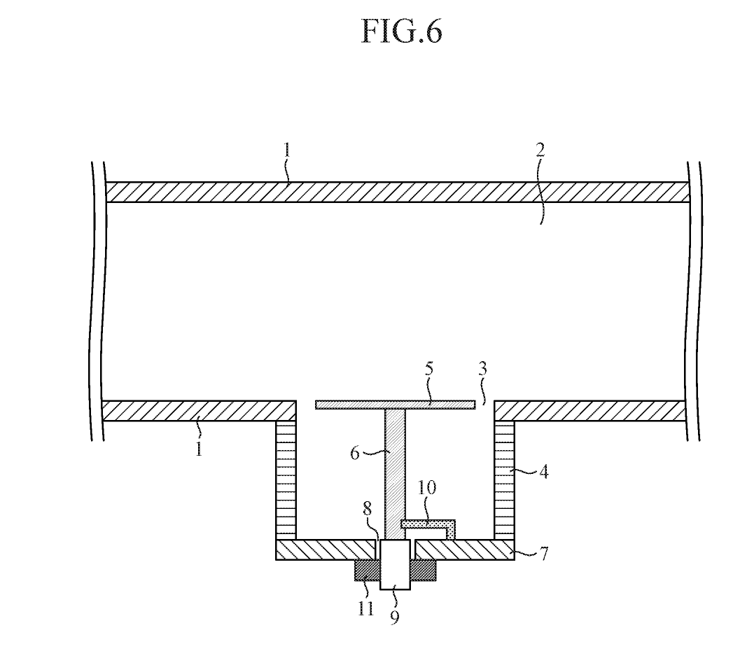

FIG. 6 is a cross-sectional view showing a partial discharge sensor of an embodiment 2 in accordance with the present invention. In FIG. 6, since the same reference numerals as those of FIG. 1 designate the same or like components, their description will be omitted.

A resin material 11 is a dielectric which is comprised of a hardening resin like an epoxy resin, for example, and is fixed to the covering 7 in a manner as to cover the hole at the center of the covering 7 through which the metal terminal 9 passes. For example, the resin material 11 is fixed to the covering 7 using screws or the like.

In the present embodiment 2, since the resin material 11 is fixed to the covering 7 in a manner as to cover the hole 8 of the covering 7, it can maintain the closed space 2 in the metallic casing 1, thereby being able to prevent the insulating gas in the closed space 2 from leaking to the outside. In addition, the resin material 11 can fix the metal terminal 9 in such a manner that the metal terminal 9 is isolated from the covering 7.

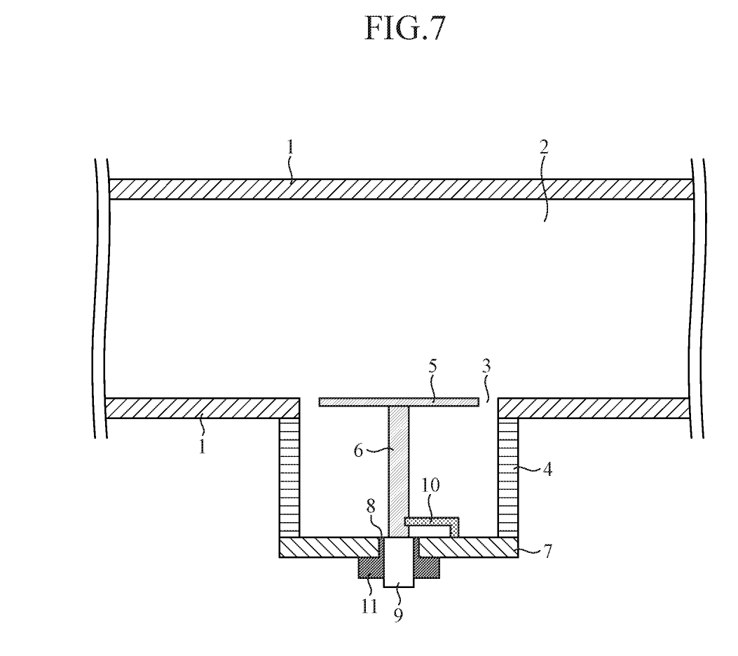

Incidentally, although it is configured that the resin material 11 does not enter the hole 8 in FIG. 6, the resin material 11 can plug up the hole 8 as shown in FIG. 7.

In this case, it is enough to design the cross-sectional shape of the metal terminal 9 and the hole 8 by considering the relative dielectric constant of the resin material 11.

When using the epoxy resin as the resin material 11, the relative dielectric constant is about four. Accordingly, the characteristic impedance of the coaxial line comprised of the hole 8 and the metal terminal 9 reduces as compared with the case where the resin material 11 is not filled.

Since the impedance Z0 of the coaxial line is set at a low value as described above in the embodiment 1, filling the resin material 11 does not cause any trouble.

### Embodiment 3

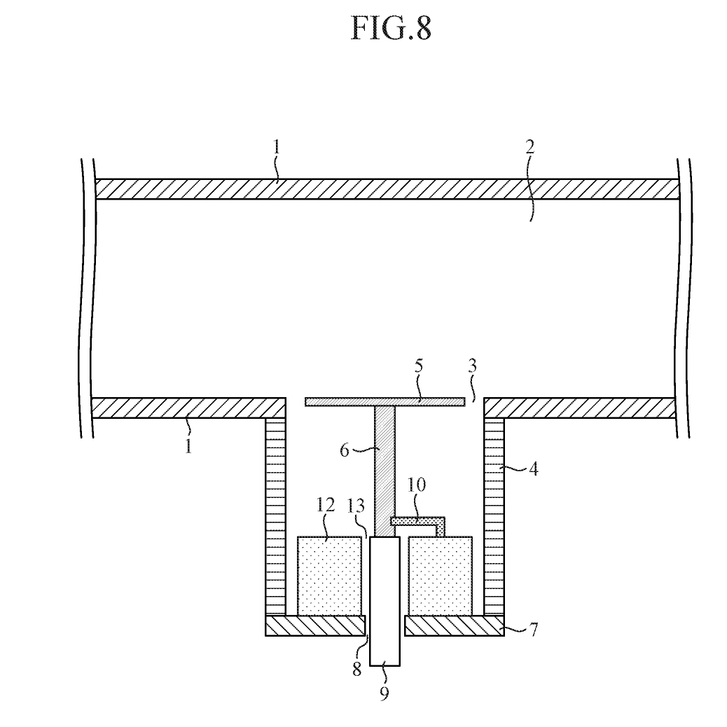

FIG. 8 is a cross-sectional view showing a partial discharge sensor of an embodiment 3 in accordance with the present invention. In FIG. 8, since the same reference numerals as those of FIG. 1 designate the same or like components, their description will be omitted.

A cylindrical metal component 12 has approximately at its center a hole 13 through which the metal terminal 9 is passed, and is disposed inside the branch pipe 4 in a manner that its bottom is electrically joined to the covering 7.

In the present embodiment 3, the short-circuit conductor 10 is joined to the top of the metal component 12 so that the short-circuit conductor 10 is electrically connected to the covering 7 via the metal component 12.

The present embodiment 3 differs from the foregoing embodiment 1 in that the metal component 12 is disposed inside the branch pipe 4.

As described in the embodiment 1, the resonance frequency of the monopole antenna comprised of the disk 5 and the metal post 6 is adjustable by designing the diameter of the disk 5 and the length of the metal post 6 in accordance with the diameter of the branch pipe 4.

However, when the length of the branch pipe 4 is longer than the length of the metal post 6, the position of the disk 5 becomes lower than the opening 3 of the metallic casing 1 in the structure of the embodiment 1.

Here, when the inside diameter of the branch pipe 4 is less than about one half of the wavelength corresponding to the frequency at the lowest limit of the frequency band of the partial discharge to be detected, the inner part of the branch pipe 4 operates as a cutoff waveguide. Thus, the high-frequency waves generated from the discharge source reduce abruptly in the branch pipe 4, thereby lowering the receiving sensitivity of the partial discharge sensor.

Since the present embodiment 3 is provided with the metal component 12 electrically connected to the covering 7, it can elevate the position of the ground potential, and can adjust the position of the disk 5 to approximately the same level of the opening 3 even if the branch pipe 4 is long. Thus, it can prevent the reduction of the receiving sensitivity of the partial discharge sensor.

As for the diameter of the hole 13 provided at the center of the metal component 12, although it can be equal to the diameter of the hole 8, they can differ from each other as shown in FIG. 8.

As for the height of the metal component 12, since it is determined from the length of the branch pipe 4 and the length of the metal post 6, it cannot be used as a design parameter to optimize the impedance of the top loaded monopole antenna comprised of the disk 5 and the metal post 6.

However, since it allows to select the characteristic impedance of the coaxial line comprised of the hole 8 and the metal terminal 9 and the characteristic impedance of the coaxial line comprised of the hole 13 and the metal terminal 9 independently, the degree of freedom of the design increases, which enables the design to broaden the band of the impedance of the antenna.

As is clear from the above, according to the present embodiment 3, it is configured in such a manner as to comprise the metal component 12 which is disposed inside the branch pipe 4 in a fashion that the metal component 12 has the hole 13 provided approximately at its center to pass through the metal terminal 9 and that its bottom is electrically joined to the covering 7. Accordingly, even when the length of the branch pipe 4 is greater than the length of the metal post 6, the present embodiment 3 offers an advantage of being able to provide a partial discharge sensor with high receiving sensitivity.

### Embodiment 4

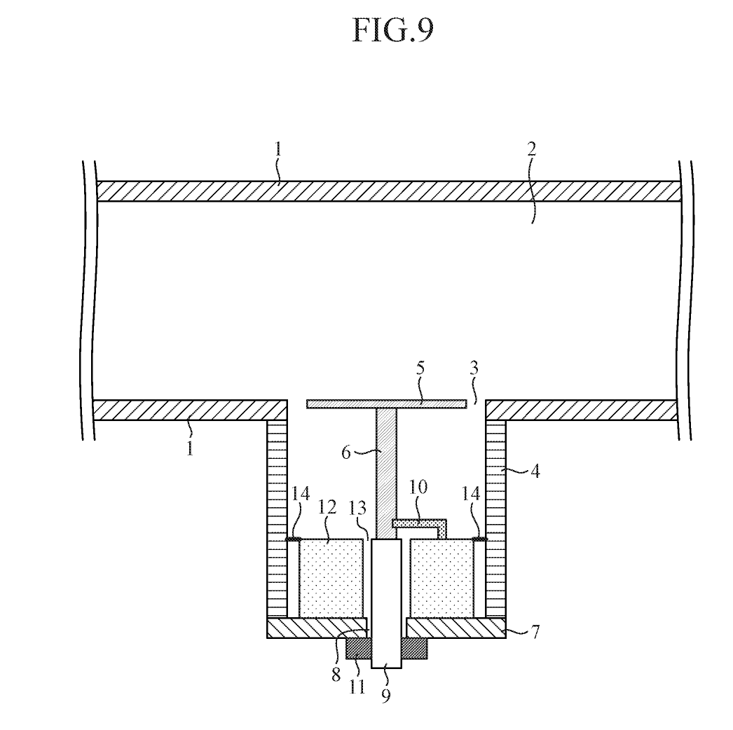

FIG. 9 is a cross-sectional view showing a partial discharge sensor of an embodiment 4 in accordance with the present invention. In FIG. 9, since the same reference numerals as those of FIG. 8 designate the same or like components, their description will be omitted.

A short-circuit conductor 14 is a connecting conductor that has its first end joined to the metal component 12 at its top, and has its second end joined to the internal surface of the branch pipe 4.

The present embodiment 4 differs from the foregoing embodiment 3 in that it comprises the short-circuit conductor 14 connecting the metal component 12 and the branch pipe 4.

Since the metal component 12 has its bottom electrically joined to the covering 7, the structure seen looking into the covering 7 from the top of the metal component 12 has a choke structure.

Accordingly, at the frequency at which the height of the metal component 12 becomes equal to (¼+n/2)λ (where λ is the wavelength and n is an integer equal to or greater than zero), the impedance seen looking into the covering 7 from the top of the metal component 12 takes a very high value which is infinite theoretically. As a result, the current across the metal component 12 and the metallic casing 1 is broken so that the sensitivity of the partial discharge sensor reduces greatly.

The present embodiment 4 is constructed so as to cause the current to low across the metal component 12 and the metallic casing 1 even at the above mentioned specific frequency by connecting the top of the metal component 12 or its neighborhood to the internal surface of the branch pipe 4 via the short-circuit conductor 14. Accordingly, the present embodiment 4 can prevent the reduction of the sensitivity of the partial discharge sensor.

Incidentally, as for the form of the short-circuit conductor 14, it is enough that it has a shape to electrically connect the top of the metal component 12 or its neighborhood to the internal surface of the branch pipe 4, and a spring or a conductive gasket is usable.

Incidentally, it is to be understood that a free combination of the individual embodiments, variations of any components of the individual embodiments or removal of any components of the individual embodiments is possible within the scope of the present invention.

### INDUSTRIAL APPLICABILITY

The present invention is applicable to a power device (such as a gas insulated switching device and a vacuum breaker) which must detect a partial discharge phenomenon that can occur inside the metallic casing.

### DESCRIPTION OF REFERENCE SYMBOLS

1 metallic casing; 2 closed space; 3 opening; 4 branch pipe; 5 disk (flat metallic conductor); 6 metal post; 7 covering (covering metallic conductor); 8 hole; 9 metal terminal; 10 short-circuit conductor; 11 resin material (dielectric), 12 metal component; 13 hole; 14 short-circuit conductor.

1. A partial discharge sensor comprising:
a cylindrical metallic casing;
a cylindrical branch pipe having its first end joined to an opening of the metallic casing;
a covering metallic conductor covering a second end of the branch pipe;
a flat metallic conductor disposed in the opening of the metallic casing in a manner that the flat metallic conductor is on the same level with an internal surface of the metallic casing without making contact with the metallic casing;
a metal post disposed inside the branch pipe in a manner that the metal post has its first end joined to the flat metallic conductor;
a metal terminal having its first end joined to a second end of the metal post, and having its second end exposed to the outside through a hole provided at the center of the covering metallic conductor; and
a short-circuit conductor having its first end joined to the metal post, and its second end joined to the covering metallic conductor, wherein
the metal terminal and the covering metallic conductor constitute a coaxial line with the metal terminal functioning as its internal conductor and the covering metallic conductor functioning as its external conductor, and
the coaxial line and the short-circuit conductor construct a parallel resonant circuit.

2. (canceled)

3. The partial discharge sensor according to claim 1, further comprising:
a dielectric fixed to the covering metallic conductor in a manner as to cover the hole at the center of the covering metallic conductor, which hole is passed through by the metal terminal.

4. The partial discharge sensor according to claim 3, wherein a part of the dielectric plugs up the hole.

5. The partial discharge sensor according to claim 1, further comprising:
a metal component that has a hole through which the metal terminal is inserted and that is disposed inside the branch pipe in a manner that its first end joined with the covering metallic conductor, wherein
the short-circuit conductor has its second end electrically connected to the covering metallic conductor via the metal component.

6. The partial discharge sensor according to claim 5, wherein
the metal component has a height equal to a result of subtracting the height of the metal post from the height of the branch pipe.

7. The partial discharge sensor according to claim 5, further comprising:
a short-circuit conductor having its first end joined to a second end of the metal component, and its second end joined to the internal surface of the branch pipe.
